(19) United States
(12) Patent Application Publication
(10) Pub. No.: US 2019/0357372 A1
(43) Pub. Date: Nov. 21, 2019

(54) WATERPROOF FASTENING ASSEMBLY

(71) Applicant: Goldtek Technology Co., Ltd., New Taipei City (TW)

(72) Inventors: LIH-SIN LEE, Taipei (TW); WANG-HUNG CHIANG, Taipei (TW)

(21) Appl. No.: 16/411,396

(22) Filed: May 14, 2019

(30) Foreign Application Priority Data
May 18, 2018 (TW) 107116900

(51) Int. Cl. H05K 5/02; H05K 5/03

(52) U.S. Cl. CPC H05K 5/0221; H05K 5/03

(57) ABSTRACT

A waterproof fastening assembly includes a base plate, a top cover, and a fastening structure arranged on the top cover. The top cover and the base plate cooperatively define a receiving space. The fastening structure includes an elastic latch, a limiting slider, and a fixing seat. The elastic latch is disposed on the fixing seat, and the limiting slider is disposed on the elastic latch. The elastic latch is configured to latch a housing to cover the receiving space. The limiting slider is configured to slide to unlatch the elastic latch from the housing.

### FIELD

The subject matter herein generally relates to a fastening structures, and more particularly to a waterproof fastening assembly.

### BACKGROUND

In a device such as a smart doorbell, when a battery of the smart doorbell needs to be replaced, a housing of the smart doorbell is first opened to remove the battery. However, a waterproof structure of the smart doorbell is generally difficult to disassemble, making it difficult to replace the battery. An improved waterproof structure is desired to enable easy opening and closing of the housing.

### BRIEF DESCRIPTION OF THE DRAWINGS

Implementations of the present disclosure will now be described, by way of embodiments, with reference to the attached figures.

FIG. 1 is an assembled, isometric view of an embodiment of a waterproof fastening assembly.

FIG. 2 is an exploded view of FIG. 1.

FIG. 3 is another exploded view of FIG. 1.

FIG. 4 is a cross-sectional view of the waterproof fastening assembly taken along line Iv-Iv in FIG. 1.

FIG. 5 is similar to FIG. 4, but showing a fastening structure during a process of unlatching a housing.

FIG. 6 is similar to FIG. 5, but showing the fastening structure unlatched from the housing.

### DETAILED DESCRIPTION

It will be appreciated that for simplicity and clarity of illustration, where appropriate, reference numerals have been repeated among the different figures to indicate corresponding or analogous elements. Additionally, numerous specific details are set forth in order to provide a thorough understanding of the embodiments described herein. However, it will be understood by those of ordinary skill in the art that the embodiments described herein can be practiced without these specific details. In other instances, methods, procedures and components have not been described in detail so as not to obscure the related relevant feature being described. The drawings are not necessarily to scale and the proportions of certain parts may be exaggerated to better illustrate details and features. The description is not to be considered as limiting the scope of the embodiments described herein.

Several definitions that apply throughout this disclosure will now be presented.

The term “coupled” is defined as connected, whether directly or indirectly through intervening components, and is not necessarily limited to physical connections. The connection can be such that the objects are permanently connected or releasably connected. The term “comprising” means “including, but not necessarily limited to”; it specifically indicates open-ended inclusion or membership in a so-described combination, group, series and the like.

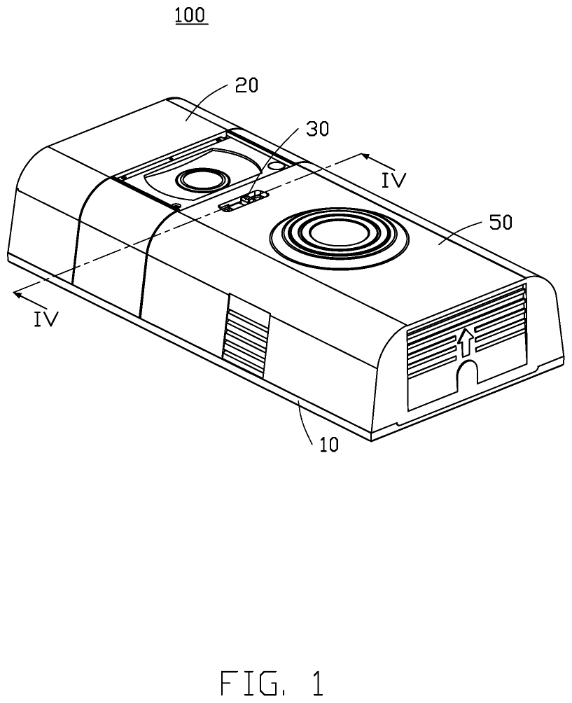

FIG. 1 shows an embodiment of a waterproof fastening assembly 100. The waterproof fastening assembly 100 includes a base plate 10, a top cover 20, and a fastening structure 30. The top cover 20 is disposed on the base plate 10, and the fastening structure 30 is configured to fasten a housing 50.

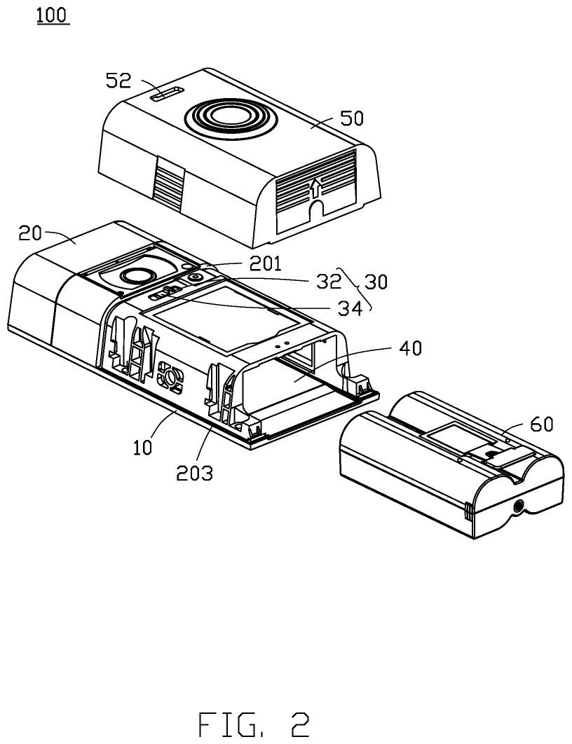

As shown in FIG. 2, the waterproof fastening assembly 100 is applied to a battery case of a smart doorbell. A receiving space 40 is defined between the top cover 20 and the base plate 10. The top cover 20 is provided with the fastening structure 30. When the housing 50 is fastened by the fastening structure 30, the housing 50 covers the receiving space 40. In one embodiment, the receiving space 40 receives a battery 60. After the battery 60 is received in the receiving space 40, the housing 50 is covered over the receiving space 40. In other embodiments, the waterproof fastening assembly 100 can be applied to any other device that needs to be sealed and waterproofed and needs to be easily opened and closed.

The receiving space 40 is sealed when the housing 50 is covered over the receiving space 40, and the housing 50 can be opened and closed conveniently. The housing 50 is opened and closed by the fastening structure 30.

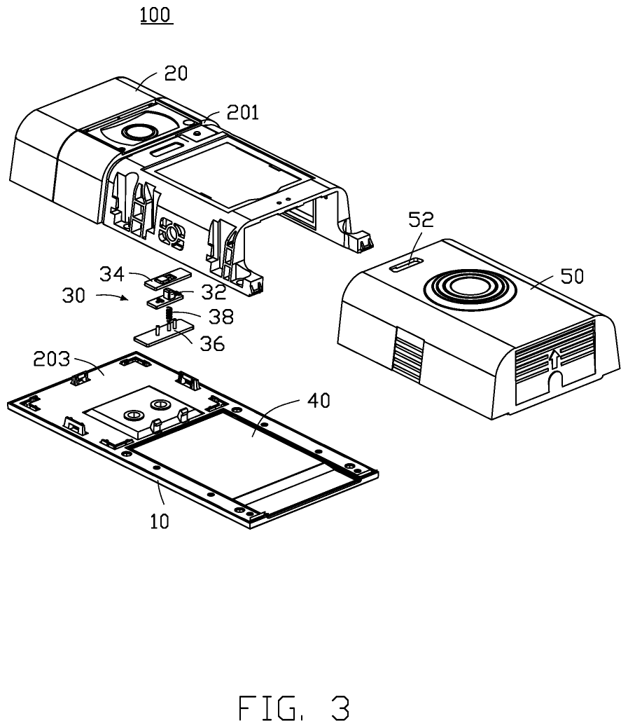

Referring to FIG. 3, the fastening structure 30 includes an elastic latch 32, a limiting slider 34, and a fixing seat 36. The elastic latch 32 is disposed on the fixing seat 36, and the limiting slider 34 is disposed on the elastic latch 32. The elastic latch 32 latches the housing 50, and the limiting slider 34 is slid to unlatch the housing 50. A first soft waterproofing sealant 201 is disposed at a joint between the housing 50 and the top cover 20, and a second waterproofing sealant 203 is disposed between the top cover 20 and the base plate 10. The first soft waterproofing sealant 201 and the second waterproofing sealant 203 effectively seal the receiving space 40 and maintain the sealed receiving space 40 when the housing 50 is opened.

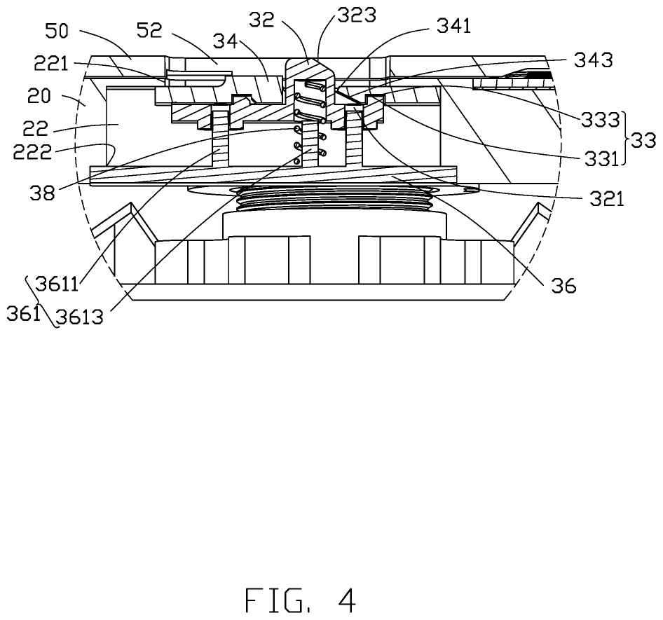

Referring to FIG. 4, the top cover 20 defines a slot 22 in which the elastic latch 32 and the limiting slider 34 are disposed. Specifically, the slot 22 includes a first opening 221 and a second opening 222. The first opening 221 is defined in an outer surface of the top cover 20 facing the housing 50, and the second opening 222 is defined in an inner surface of the top cover 20 facing the base plate 10. The housing 50 defines a fastening hole 52 aligned with the slot 22. Thus, when the housing 50 is engaged with the top cover 20, the fastening hole 52 is aligned with the first opening 221 of the slot 22.

The fixing seat 36 is arranged at the second opening 222. The elastic latch 32 and the limiting slider 34 are arranged at the first opening 221. The fixing seat 36 includes at least one guiding rod 361 extending into the slot 22. The guiding rod 361 is configured to sleeve an elastic member 38 to elastically mount the elastic latch 32 on the fixing seat 36. In one embodiment, the guiding rod 361 includes two first guiding rods 3611 and a second guiding rod 3613. The first guiding rods 3611 are received through a hole 321 of the elastic latch 32 to guide elastic displacement of the elastic latch 32 on the fixing seat 36. The second guiding rod 3613 sleeves the elastic member 38 to apply an elastic force of the elastic member 38 on the elastic latch 32. The elastic latch 32 is biased by the elastic force of the elastic member 38 to abut against the limiting slider 34, and the limiting slider 34 is held in the first opening 221 of the slot 22.

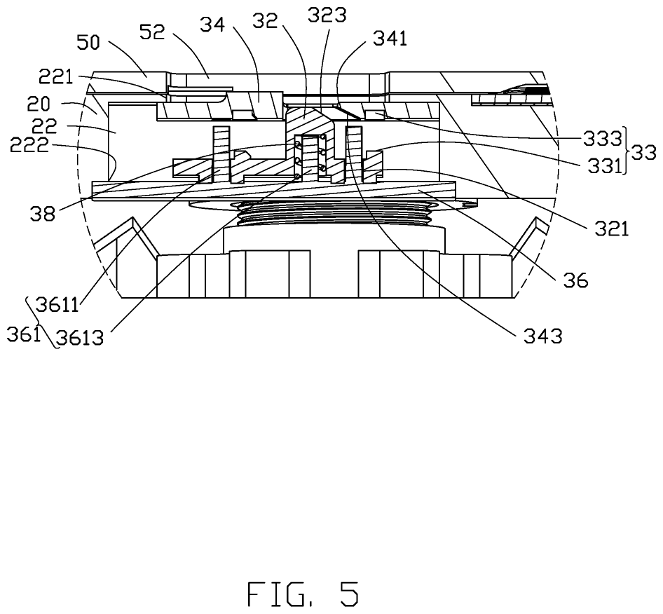

A latching structure 33 is formed by the elastic latch 32 and the limiting slider 34. The latching structure 33 includes at least one protrusion 331 and at least one recess 333. The protrusion 331 is formed on a surface of the elastic latch 32, and the recess 333 is defined in a surface of the limiting slider 34 facing the elastic latch 32. When the elastic latch 32 abuts against the limiting slider 34 to insert the protrusion 331 into the recess 333 (as shown in FIG. 4), the elastic latch 32 protrudes through the first opening 221. When the elastic latch 32 is pressed into the first opening 221, the protrusion 331 is removed out of the recess 333 (as shown in FIG. 5).

In one embodiment, the limiting slider 34 defines a guiding groove 341 for guiding the elastic latch 32 to protrude through the first opening 221. An inner edge surface of the guiding groove 341 forms a pushing surface 343. By sliding the limiting slider 34, the pushing surface 343 drives the elastic latch 32 to retract into the slot 22 (as shown in FIG. 5). When the elastic latch 32 is pressed against the limiting slider 34 by the elastic force of the elastic member 38 (shown in FIG. 4), the protrusion 331 is inserted into the recess 333 to restrict movement between the elastic latch 32 and the limiting slider 34. Thus, when the elastic latch 32 protrudes from the first opening 221, the latching structure 33 fixes the elastic latch 32 and the limiting slider 34 in position at the first opening 221. When the housing 50 is engaged with the top cover 20, the fastening hole 52 is aligned with the first opening 221, and the elastic latch 32 protruding through the first opening 221 can maintain engagement of the housing 50 with the top cover 20.

Referring to FIG. 5, to unlatch the fastening structure 30, the elastic latch 32 is pressed into the first opening 221 to separate the elastic latch 32 from the guiding groove 341 and move the elastic latch 32 into the slot 22, thereby compressing the elastic member 38 and separating the elastic latch 32 from the limiting slider 34. The elastic latch 32 includes an inclined surface 323 facing the pushing surface 343. The first guiding rods 3611 pass through the elastic latch 32 to maintain a stable position of the elastic latch 32.

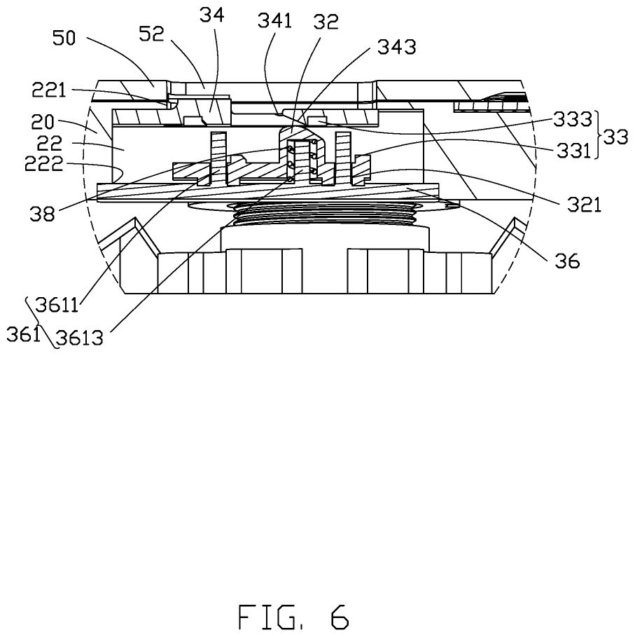

Referring to FIG. 6, to disassemble the housing 50 from the top cover 20, the limiting slider 34 is driven to slide relative to the elastic latch 32, so that the pushing surface 343 pushes the elastic latch 32 to further retract into the slot 22 by engagement between the pushing surface 343 and the inclined surface 323, and then the housing 50 is removed. Specifically, when the elastic latch 32 is retracted into the slot 22, the elastic latch 32 is unlatched from the housing 50 to release the housing 50.

To assemble the housing 50 to the top cover 20, the housing 50 is first engaged with the top cover 20 such that the fastening hole 52 is aligned with the first opening 221. Then, the limiting slider 34 is driven to slide to align the guiding groove 341 of the limiting slider 34 with the elastic latch 32, and the elastic latch 32 is driven by a restoring force of the elastic member 38 to protrude from the guiding groove 341 through the first opening 221 to latch the housing 50 to the top cover 20. A joint between the top cover 20 and the housing 50 is located at a periphery of an outer surface of the top cover 20, and the first soft waterproofing sealant 201 is disposed on the periphery of the outer surface of the top cover 20. The first waterproofing sealant 201 is located opposite to a periphery of a joint end of the housing 50. The second waterproofing sealant 203 is disposed on a periphery of the receiving space 40 between the base plate 10 and the top cover 20 (as shown in FIG. 2). Therefore, the first soft waterproofing sealant 201 and the second soft waterproofing sealant 203 seal the receiving space 40.

The housing 50 is latched and unlatched by the elastic latch 32 and the limiting slider 34 to facilitate opening and closing of the receiving space 40. Thus, the waterproof fastening assembly 100 has a simple structure.

The embodiments shown and described above are only examples. Even though numerous characteristics and advantages of the present technology have been set forth in the foregoing description, together with details of the structure and function of the present disclosure, the disclosure is illustrative only, and changes may be made in the detail, including in matters of shape, size and arrangement of the parts within the principles of the present disclosure up to, and including, the full extent established by the broad general meaning of the terms used in the claims.

What is claimed is:

1. A waterproof fastening assembly comprising:
a base plate;
a top cover; and
a fastening structure arranged on the top cover; wherein:
the top cover and the base plate cooperatively define a receiving space;
the fastening structure comprises an elastic latch, a limiting slider, and a fixing seat;
the elastic latch is disposed on the fixing seat, and the limiting slider is disposed on the elastic latch;
the elastic latch is configured to latch a housing to cover the receiving space;
the limiting slider is configured to slide to unlatch the elastic latch from the housing.

2. The waterproof fastening assembly of claim 1, wherein:
the top cover defines a slot comprising a first opening and a second opening;
the first opening is defined at an outer surface of the top cover and faces the housing;
the second opening is defined at an inner surface of the top cover and faces the base plate;
the fixing seat is arranged at the second opening;
the elastic latch and the limiting slider are arranged at the first opening.

3. The waterproof fastening assembly of claim 2, wherein:
when the elastic latch latches the housing, the first opening is aligned with a fastening hole of the housing.

4. The waterproof fastening assembly of claim 2, wherein:
the fixing seat comprises at least one guiding rod extending into the slot;
the at least one guiding rod is coupled to the elastic latch;
the at least one guiding rod comprises at least one elastic member to elastically mount the elastic latch on the fixing seat.

5. The waterproof fastening assembly of claim 4, wherein:
the guiding rod comprises a first guiding rod and a second guiding rod;
the first guiding rod is received through a hole defined in the elastic latch to guide elastic displacement of the elastic latch on the fixing seat;
the second guiding rod sleeves the elastic member.

6. The waterproof fastening assembly of claim 5, wherein:
the limiting slider defines a guiding groove for guiding the elastic latch to protrude through the first opening;
an inner edge surface of the guiding groove forms a pushing surface;
the limiting slider is configured to slide to cause the pushing surface to drive the elastic latch to retract into the slot.

7. The waterproof fastening assembly of claim 6, wherein:
a side of the elastic latch comprises an inclined surface to be aligned with the pushing surface;
the pushing surface pushes the elastic latch by engagement between the pushing surface and the inclined surface.

8. The waterproof fastening assembly of claim 2, wherein:
the elastic latch and the limiting slider form a latching structure;
the latching structure comprises at least one protrusion and at least one recess;
the protrusion is formed on a surface of the elastic latch, and the recess is defined in a surface of the limiting slider facing the elastic latch;
when the protrusion is inserted into the recess, the elastic latch protrudes through the first opening;
when the elastic latch is pressed into the first opening, the protrusion is removed out of the recess.

9. The waterproof fastening assembly of claim 1, wherein:
a first soft waterproofing sealant is disposed at a joint between the housing and the top cover;
a second waterproofing sealant is disposed between the top cover and the base plate.

10. A fastening structure arranged on a top cover of a device, the fastening structure comprising:
an elastic latch;
a limiting slider; and
a fixing seat; wherein:
the elastic latch is disposed on the fixing seat, and the limiting slider is disposed on the elastic latch;
the elastic latch is configured to latch a housing of the device;
the limiting slider is configured to slide to unlatch the elastic latch from the housing.

11. The fastening structure of claim 10, wherein:
the elastic latch and the limiting slider are arranged at a first opening of the slot defined in an outer surface of the top cover;
the fixing seat is arranged at a second opening of the slot defined in an inner surface of the top cover.

12. The fastening structure of claim 11, wherein:
when the elastic latch latches the housing, the first opening is aligned with a fastening hole of the housing.

13. The fastening structure of claim 12, wherein:
the fixing seat comprises at least one guiding rod extending into the slot;
the at least one guiding rod is coupled to the elastic latch;
the at least one guiding rod comprises at least one elastic member to elastically mount the elastic latch on the fixing seat.

14. The fastening structure of claim 13, wherein:
the guiding rod comprises a first guiding rod and a second guiding rod;
the first guiding rod is received through a hole defined in the elastic latch to guide elastic displacement of the elastic latch on the fixing seat;
the second guiding rod sleeves the elastic member.

15. The fastening structure of claim 14, wherein:
the limiting slider defines a guiding groove for guiding the elastic latch to protrude through the first opening;
an inner edge surface of the guiding groove forms a pushing surface;
the limiting slider is configured to slide to cause the pushing surface to drive the elastic latch to retract into the slot.

16. The fastening structure of claim 15, wherein:
a side of the elastic latch comprises an inclined surface to be aligned with the pushing surface;
the pushing surface pushes the elastic latch by engagement between the pushing surface and the inclined surface.

17. The fastening structure of claim 16, wherein:
the elastic latch and the limiting slider form a latching structure;
the latching structure comprises at least one protrusion and at least one recess;
the protrusion is formed on a surface of the elastic latch, and the recess is defined in a surface of the limiting slider facing the elastic latch;
when the protrusion is inserted into the recess, the elastic latch protrudes through the first opening;
when the elastic latch is pressed into the first opening, the protrusion is removed out of the recess.

18. The fastening structure of claim 17, wherein:
the elastic latch and the limiting slider form a latching structure;
the latching structure comprises at least one protrusion and at least one recess;
the protrusion is formed on a surface of the elastic latch, and the recess is defined in a surface of the limiting slider facing the elastic latch;
when the protrusion is inserted into the recess, the elastic latch protrudes through the first opening;
when the elastic latch is pressed into the first opening, the protrusion is removed out of the recess.
